(19) United States
(12) Patent Application Publication
(10) Pub. No.: US 2010/0315297 A1
(43) Pub. Date: Dec. 16, 2010

(54) Wireless Device and Method for Manufacturing the Same

(76) Inventors: Min-Chung Wu, Taoyuan County (TW); Shao-Chin Lo, Miaoli City (TW)

Correspondence Address: NORTH AMERICA INTELLECTUAL PROPERTY CORPORATION, P.O. BOX 506, MERRIFIELD, VA, 22116, US

(21) Appl. No.: 12/562,122

(22) Filed: Sep. 17, 2009

Related U.S. Application Data
(60) Provisional application No. 61/186,381, filed on Jun. 12, 2009.

(51) Int. Cl. H01Q 1/24; H05K 13/00

(52) U.S. Cl. 343/702; 29/592.1

(57) ABSTRACT

The present invention discloses a wireless device, which includes a housing and a printed circuit board (PCB). The housing has an opening at one end, and includes at least one antenna each formed on one side of the housing. The PCB, disposed inside the housing, includes a plurality of contacts, formed on both sides of the PCB, for coupling to the at least one antenna such that vertical position of the PCB is fixed by the at least one antenna. The housing and the PCB further form a connector of the wireless device at the opening.

### CROSS REFERENCE TO RELATED APPLICATIONS

This application claims the benefit of U.S. Provisional Application No. 61/186,381, filed on Jun. 12, 2009 and entitled “Wireless Device and Method for Manufacturing the Same”, the contents of which are incorporated herein by reference.

### BACKGROUND OF THE INVENTION

1. Field of the Invention

The present invention relates to a wireless device and a method for manufacturing the same, and more particularly, to a wireless device with compact size and a method for manufacturing the same with high yield.

2. Description of the Prior Art

With the trends of compact consumer electronics products, mechanical design of a wireless USB device is required to reduce the product size, to simplify the assembly process, to enhance the manufacturing yield, and to lower the production costs.

As shown in FIG. 1, a conventional wireless USB device 10, such as a WLAN USB dongle, can be taken as a combination of a connector 100, a printed circuit board (PCB) 102 and a planar printed antenna 104. Thus, a length of the wireless USB device 10 is equal to the sum of the lengths of the connector 100, the PCB 102 and the planar printed antenna 104, i.e. L=L1+L2+L3. Since the size of the connector 100 is defined and limited by the USB specification, the only way to minimize the size of the wireless USB device 10 is to minimize the sizes of the PCB 102 and the antenna 104. However, doing so would increase difficulties in circuit design on the PCB 102 and the pattern of the antenna 104 and could possibly deteriorate the performance of the wireless device 10 and the manufacturing yield.

Therefore, there's a need to minimize the size of a wireless USB device without losing the performance.

### SUMMARY OF THE INVENTION

It is therefore an objective of the present invention to provide a compact wireless device.

It is therefore another objective of the present invention to provide a method for manufacturing a compact wireless device with high yield.

The present invention discloses a wireless device, which includes a housing and a printed circuit board (PCB). The housing, having an opening at one end, includes at least one antenna, each of the at least one antenna being formed on one side of the housing. The PCB, disposed inside the housing, includes a plurality of contacts, for coupling to the at least one antenna. The housing and the PCB further form a connector of the wireless device at the opening.

The present invention also discloses a method for manufacturing a wireless device, which includes the steps of, providing a housing having an opening at one end and comprising at least one antenna each formed on one side of the housing; and inserting a printed circuit board (PCB) into the housing, the PCB comprising a plurality of contacts, for coupling to the at least one antenna; wherein the housing and the PCB further form a connector of the wireless device at the opening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration of a conventional wireless device.

FIG. 2 is an illustration of a wireless device according to an embodiment of the present invention.

FIG. 3 is an illustration of a first antenna of the wireless device in FIG. 2.

FIG. 4 is an illustration of a second antenna of the wireless device in FIG. 2.

FIG. 5 is an illustration of a front view of the wireless device in FIG. 2.

FIG. 6 is an illustration of a side view of the wireless device in FIG. 2.

FIG. 7 is an illustration of a process for manufacturing a wireless USB device according to an embodiment of the present invention.

FIG. 8 illustrates an exemplary embodiment of the process in FIG. 7.

### DETAILED DESCRIPTION

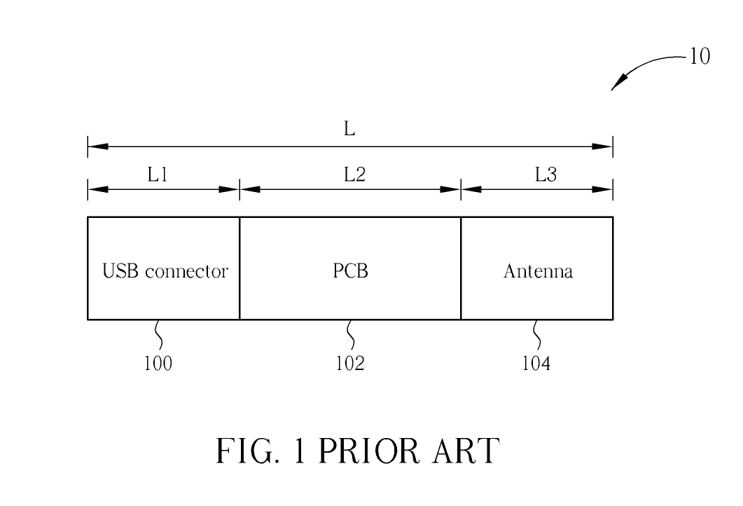

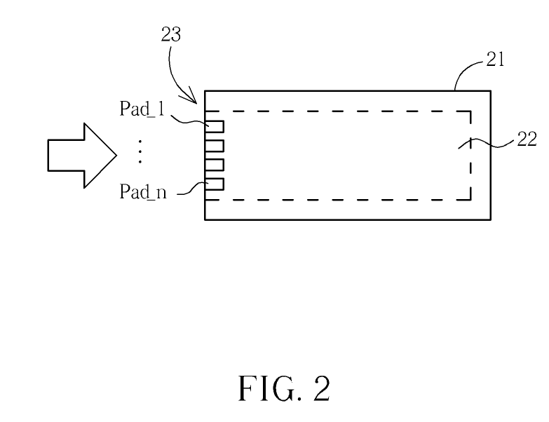

Please refer to FIG. 2, which is an illustration of a wireless USB device 20 according to an embodiment of the present invention. The wireless USB device 20 includes a housing 21 and a printed circuit board (PCB) 22. The housing 21 has an opening 23 at one end, and includes at least one antenna (not shown), each formed on one side of the housing 21. The PCB 22 is disposed inside the housing 21 to save space, and includes a plurality of contacts (not shown), formed on both sides of the PCB 22, for coupling to the at least one antenna, such that a vertical position of the PCB 22 is fixed by the at least one antenna. In addition, the housing 21 and the PCB 22 further form a USB connector at the opening 23, for connecting to a portable or host device, such as a notebook. The PCB 22 includes a plurality of connecting pads PAD_1 to PAD_n, functioned as the USB connector for receiving or transmitting signals from a portable device, such as a notebook. Since the housing 21 is made of conductive material, a part of the housing 21 is used as the antennas of the wireless USB device 20. Thus, the size required for the antenna can thus be reduced. Comparing FIG. 2 to FIG. 1, the length L′ of the wireless USB device 20 according to the present invention is much smaller than the length L of the conventional wireless USB device 10 as shown in FIG. 1. Detailed descriptions of the wireless USB device 20 are further illustrated in the following.

In this embodiment, the wireless USB device 20 is used for an IEEE 802.11n WLAN application, such that there should be two antennas individually form on two lateral sides of the housing 21. Note that, the number of antennas included by the housing 21 of the wireless USB device 20 depends on system requirements.

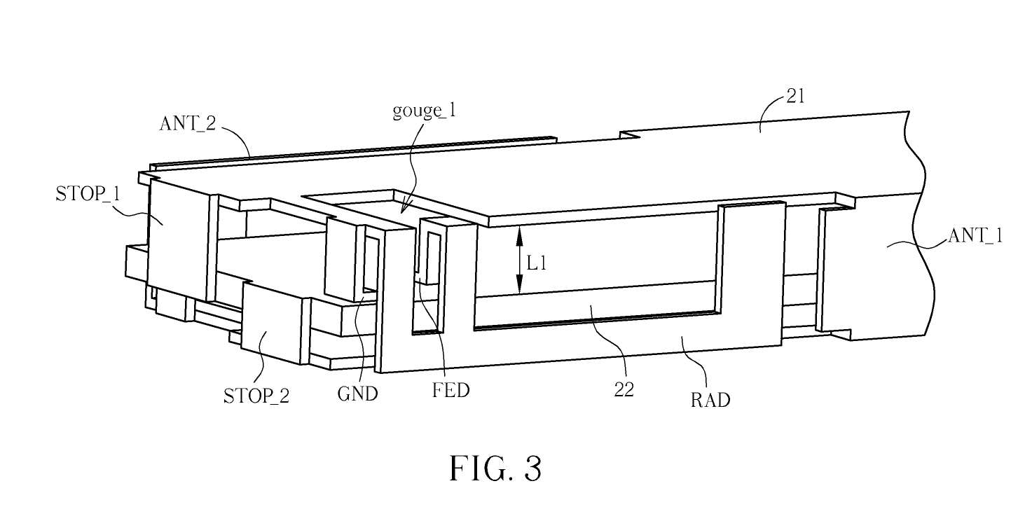

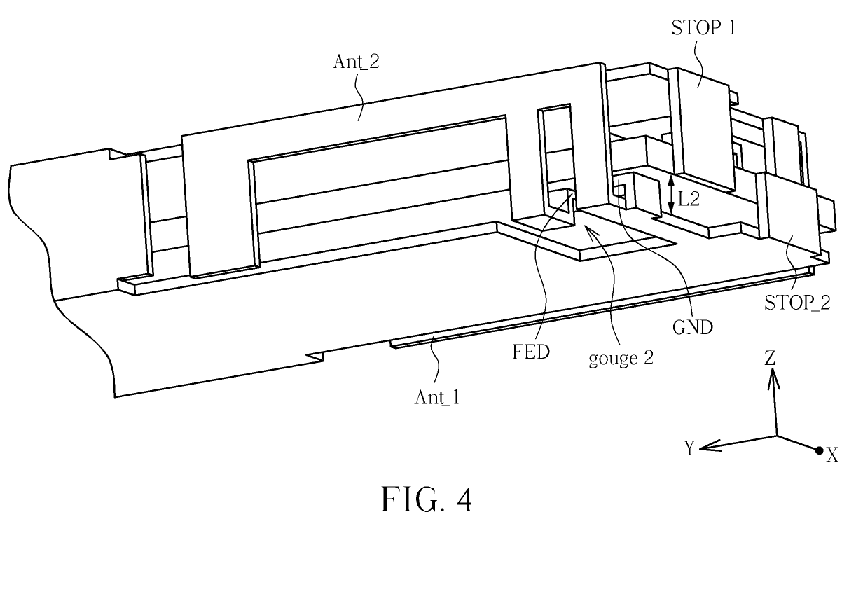

Please refer to FIG. 3 and FIG. 4, which illustrate the antennas of the wireless USB device 20. The housing 21 is a hollow structure made of conductive material, such as iron, copper, or other metals. The hollow structure is so designed such that the PCB 22 can be disposed inside the housing 21. In FIG. 3 and FIG. 4, the housing 21 includes two antennas, a first antenna Ant_1 and a second antenna Ant_2 formed on the lateral sides of the housing 21. Alternatively, the antennas Ant_1 and Ant_2 can also be formed on the top and bottom sides of the housing 21 (not shown). Each of the antennas Ant_1 and Ant_2 includes a radiator RAD, a feeding terminal FED and a grounding terminal GND. The feeding terminals FED are used to transmit signals from the PCB 22 to the antennas Ant_1 and Ant_2, respectively. The feeding terminal FED and the grounding terminal GND of the first antenna Ant_1 are extended from the housing 21 to the top layer of the PCB 22 for coupling to the contacts (not shown) on the PCB 22, as shown in FIG. 3, while the feeding terminal FED and the grounding terminal GND of the second antenna Ant_2 are extended from the opposite side of the housing 21 to the bottom layer of the PCB 22 for coupling to the contacts (not shown) on the PCB 22, as shown in FIG. 4. With the feeding terminals FED and the grounding terminals GND of the antennas Ant_1 and Ant_2 coupled to the top and the bottom sides of the PCB 22, the vertical position of the PCB 22 can be fixed inside the housing 21.

Please note that the antennas Ant_1 and Ant_2 not only can be formed as a part of the housing 21, but also can be formed separately. If the antennas Ant_1 and Ant_2 are formed with the housing 21, the cost and time required can be further reduced and the strength of the whole structure is also improved. No matter the antennas Ant_1 and Ant_2 are formed with the housing 21 or separately, the grounding terminals GND of the antennas Ant_1 and Ant_2 can optionally be coupled to the housing 21 to provide a better grounding effect. Besides, the first and the second antennas Ant_1 and Ant_2 can be any kind of antennas, for example but not limited to, a monopole antenna, a dipole antenna, a circularly polarized antenna, a loop antenna, a planer inverted F antenna (PIFA), a dual band antenna, a three-dimensional antenna, and a planar antenna.

Moreover, in the wireless USB device 20, the housing 21 can optionally include at least one stop at an end opposite to the opening 23, such as stops Stop_1 and Stop_2 in FIG. 3 and FIG. 4, to further constrain the possible movement of the PCB 22, such that the horizontal position of the PCB 22 can also be fixed. In addition, the housing 21 can further include a plurality of gouges on the top and bottom side, such as gouges Gouge_1 and Gouge_2 in FIG. 3 and FIG. 4. These gouges are prepared for further processing to couple the antennas Ant_1 and Ant_2 to the contacts on the top and bottom sides of the PCB 22. The processing, for example, can be welding. The gouges Gouge_1 and Gouge_2 on the top and bottom side of the housing 21 are also optional.

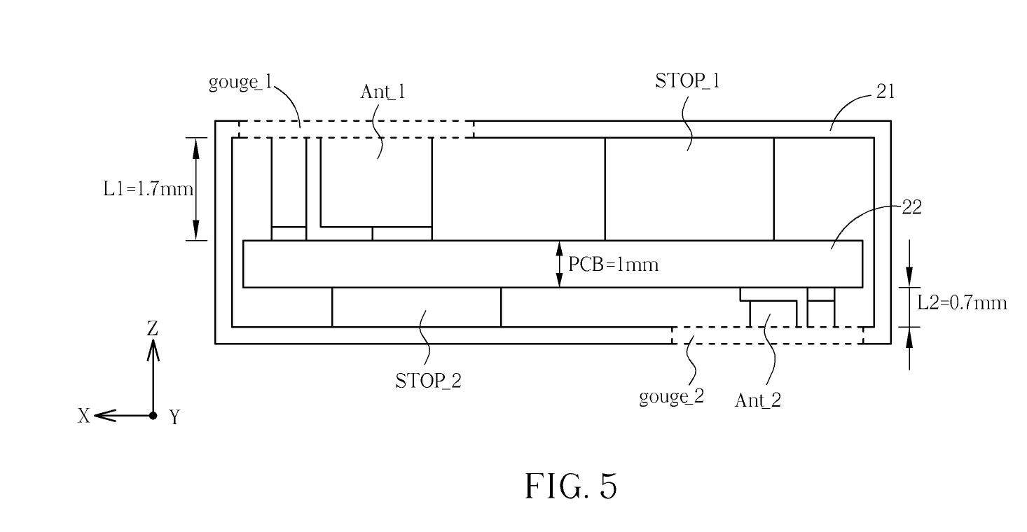

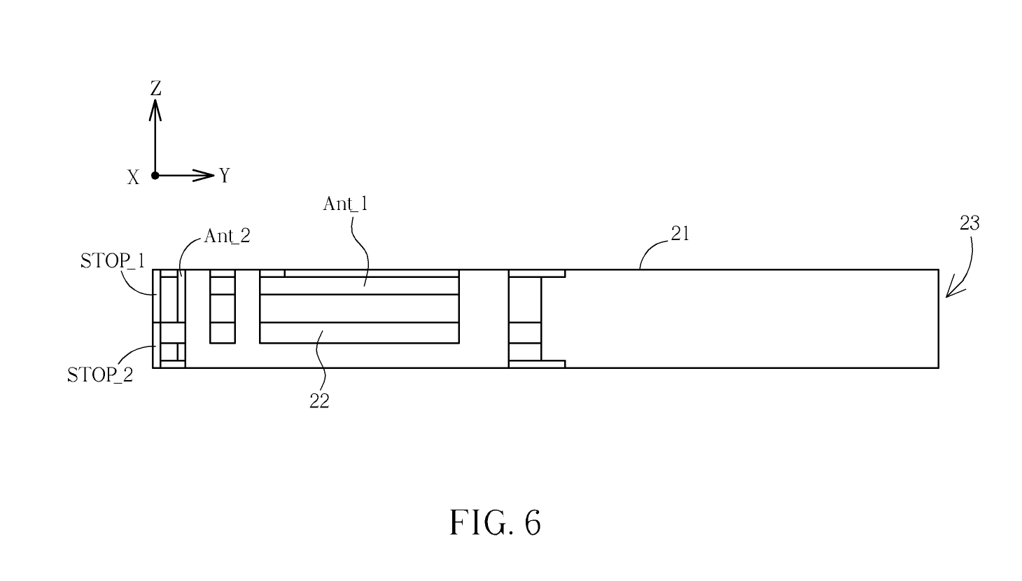

Please refer to FIG. 5 and FIG. 6, which illustrate a front view and a side view of the wireless USB device 20. In order to comply with the standard size of a USB connector, one end of the housing 21, which forms the connector of the wireless USB device 20, has a standard size. The space within the housing 21 is therefore limited. One exemplary arrangement is to have the thickness of the PCB 22 as 1 mm, the height L1 between the grounding terminal GND of the first antenna ANT_1 and the housing 21 as 1.7 mm, and the height L2 between the grounding terminal GND of the second antenna ANT_2 and the housing 21 as 0.7 mm. The above-mentioned size is only for exemplary illustration and can be a combination of any sizes as long as the PCB 22 can be disposed at a suitable position inside the housing 21 and the connector formed by the housing 21 and the PCB 22 can comply with the required specifications.

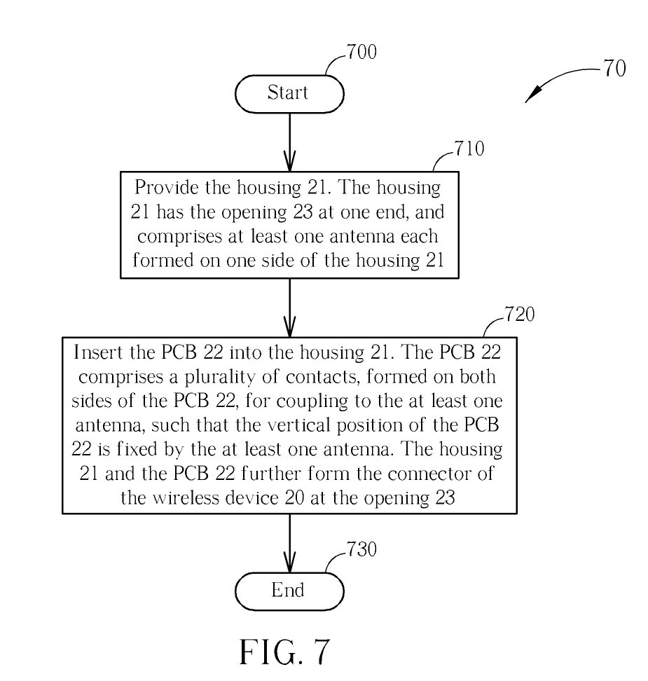

Please refer to FIG. 7, which illustrates a process 70 for manufacturing the wireless USB device 20 according to an embodiment of the present invention. The process 70 includes the following steps:

Step 700: Start.

Step 710: Provide the housing 21. The housing 21 has the opening 23 at one end, and comprises at least one antenna each formed on one side of the housing 21.

Step 720: Insert the PCB 22 into the housing 21. The PCB 22 comprises a plurality of contacts, formed on both sides of the PCB 22, for coupling to the at least one antenna, such that the vertical position of the PCB 22 is fixed by the at least one antenna. The housing 21 and the PCB 22 further form the connector of the wireless device 20 at the opening 23.

Step 730: End.

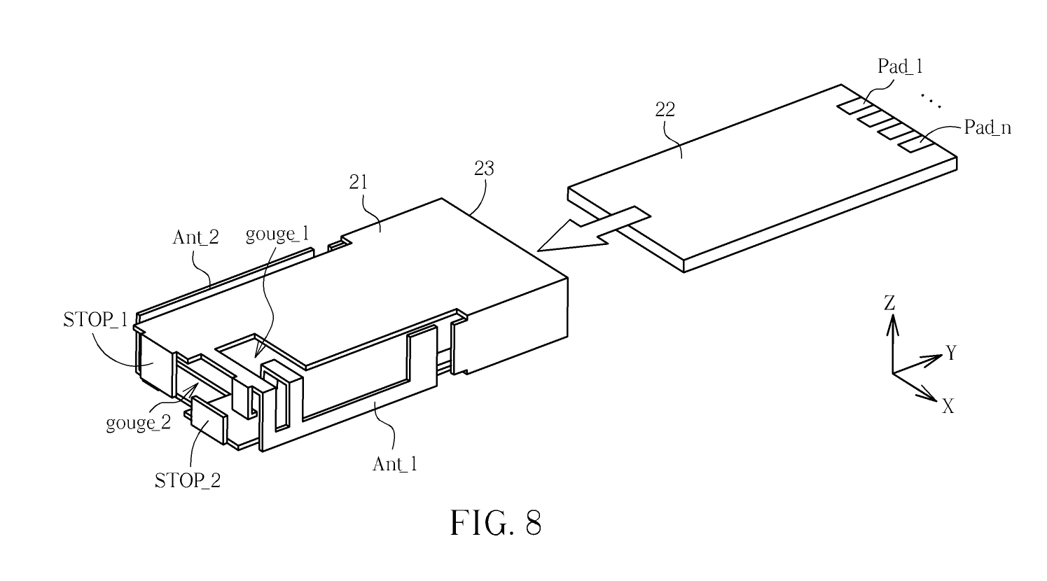

With the housing 21 and the antennas Ant_1 and Ant_2 formed according to the aforementioned embodiments, the PCB 22 is inserted into the housing 21, as shown in FIG. 8, and the grounding terminals GND and the feeding terminals FED of the two antennas Ant_1 and Ant_2, and optionally, the stops Stop_1 and Stop_2 can hold the PCB 22 in position to prevent possible movement. Further processing steps, such as welding, can then be performed through the gouges Gouge_1 and Gouge_2. Therefore, by forming the antennas Ant_1 and Ant_2 together with the housing 21 and disposing the PCB 22 inside the housing 21 to form the USB connector, the size of the wireless USB device 20 can be significantly reduced. Beside, by designing the feeding terminals FED and the grounding terminals GND of the antennas Ant_1 and Ant_2 to clamp the PCB 22, the wireless USB device 20 of the present invention can further simplify the assembly process, enhance the manufacturing yield, and lower the production costs as well.

In summary, the present invention provides a wireless USB device with compact size and a method for manufacturing the same. The total length of the wireless USB device is significantly reduced. The cost, manufacturing time, and the yield of the wireless USB device can also be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wireless device comprising:
a housing, having an opening at one end, comprising at least one antenna, wherein the at least one antenna is formed on one side of the housing; and
a printed circuit board (PCB), disposed inside the housing, comprising a plurality of contacts for coupling to the at least one antenna;
wherein the housing and the PCB further form a connector of the wireless device at the opening.

2. The wireless device of claim 1, wherein each of the at least one antenna comprises a radiator, a feeding terminal and a grounding terminal, and the feeding terminal and the grounding terminal are extended from the housing to one side of the PCB for coupling to the plurality of contacts of the PCB, respectively.

3. The wireless device of claim 1, wherein the housing further comprises a plurality of stops, formed at an end opposite to the opening, for constraining movement of the PCB.

4. The wireless device of claim 1, wherein the housing further comprises at least one gouge, for facilitating welding the at least one antenna to the plurality of contacts of the PCB.

5. The wireless device of claim 1, wherein the PCB further comprises a plurality of connecting pads for receiving or transmitting signals.

6. The wireless device of claim 1, wherein the number of the at least one antenna is two, and the two antennas are formed on opposite sides of the housing.

7. The wireless device of claim 1 is a wireless USB device.

8. A method for manufacturing a wireless device, the method comprising:
providing a housing having an opening at one end and comprising at least one antenna each formed on one side of the housing; and
inserting a printed circuit board (PCB) into the housing, the PCB comprising a plurality of contacts, formed on both sides of the PCB, for coupling to the at least one antenna;
wherein the housing and the PCB further form a connector of the wireless device at the opening.

9. The method of claim 8, wherein each of the at least one antenna comprises a radiator, a feeding terminal and a grounding terminal, and the feeding terminal and the grounding terminal are extended from the housing to one side of the PCB for coupling to the plurality of contacts of the PCB, respectively.

10. The method of claim 8, wherein the housing further comprises a plurality of stops, formed at an end opposite to the opening, for constraining movement of the PCB.

11. The method of claim 8, wherein the housing further comprises at least one gouge, for facilitating welding the at least one antenna to the plurality of contacts of the PCB.

12. The method of claim 8, wherein the PCB further comprises a plurality of connecting pads for receiving or transmitting signals.

13. The method of claim 8, wherein the number of the at least one antenna is two, and the two antennas are formed on opposite sides of the housing.

14. The method of claim 8, wherein the wireless device is a wireless USB device.
